(19) United States
(12) Patent Application Publication
(10) Pub. No.: US 2015/0214132 A1
(43) Pub. Date: Jul. 30, 2015

(54) Low-Profile Heat Sink with Fine-Structure Patterned Fins for Increased Heat Transfer

(71) Applicant: DiCon Fiberoptics, Inc., Richmond, CA (US)

(72) Inventor: Ho-Shang Lee, El Sobrante, CA (US)

(21) Appl. No.: 14/670,947

(22) Filed: Mar. 27, 2015

Related U.S. Application Data
(63) Continuation of application No. 13/049,707, filed on Mar. 16, 2011.

(51) Int. Cl. H01L 23/367; B23P 15/26

(52) U.S. Cl. CPC H01L 23/3677; B23P 15/26

(57) ABSTRACT

In one embodiment, a device for transferring heat comprises a base member and a first array of pin fins supported by the base member, the pin fins having an aspect ratio of not less than about 10, and the pin fins being not more than about 0.3 mm in equivalent diameter and not more than about 3 mm in length, either one or both of the base member and pin fins comprising a metallic or semiconductor material. To form this device, a substrate is provided. A pattern is formed on the substrate, the pattern having holes therein or in the form of dots with cross-sectional dimensions of not more than about 0.3 mm. Pin fins supported by the substrate are formed, where the pin fins have an aspect ratio of not less than about 10, and not more than about 0.3 mm in equivalent diameter and not more than about 3 mm in length. Either one or both of the base member and pin fins comprise a metallic or semiconductor material. The pattern is then removed.

### CROSS-RELATED APPLICATION

This application is a continuation of U.S. Application No. 13/049,707 filed Mar. 16, 2011, and is herein incorporated in its entirety by this reference.

### BACKGROUND

Electronic components or devices generate heat locally. It is desirable to extract or remove this heat, to bring down the temperature of the components or devices, in order to increase their performance and enhance component reliability. The heat generated by electronic components can be transported to other places or locations through the use of thermally conductive materials or devices such as heat pipes. However, eventually the heat has to be dumped to the surrounding fluid medium, via some form of heat sink. The efficiency of the heat transfer to the surrounding medium (for simplicity, air is used as the example in the description of the present patent application; however, other fluid media such as water or other liquids and gases are also applicable) by the heat sink depends on the geometry of the heat sink, the contact surface with the air (or other fluid medium), the flow field around the heat sink, and the material properties of air. The transfer of heat from the heat sink to the air is usually one of the major thermal resistances of the full thermal system.

The heat transfer between a heat sink and air is governed by:

Q=hₜA(T_{HS}−T∞) Equation 1

where Q is the amount of heat transferred to the air, hₜ is the average heat transfer coefficient, A is the contact surface of the heat sink with the medium, T_{HS} is the average heat sink temperature, and T∞ is the air temperature in free stream.

Many types of geometries for heat sinks have been introduced for forced-air and natural convection systems, respectively. However, no matter how the geometry is arranged, the contact surface with the air medium is either limited, or it hinders the flow field such that the heat transfer coefficient is herein reduced. The length of the fins of a typical heat sink for electronic components is typically on the order of ten times (or more) of the fin diameter. Since the fins are typically made using an extrusion or forging process, their diameters cannot be too small, since very thin fins may break in the process. Hence the fin length is typically on the order of tens of millimeters, resulting in bulky heat sinks. The present invention introduces fine-structure designs and their manufacturing methods to heat sinks, to tremendously increase the contact surface with air, to increase heat flux density across the heat sink, to reduce the drag force on the flow of the fluid medium around the heat sink, and at the same time to keep the heat sink compact, with a low profile. As a result of their low profile, multiple fine-structure patterned (herein FSP) heat sinks of the present invention can be stacked up for greater overall heat transfer, while retaining compact dimensions. The present invention creates fine-structure patterned fins that protrude from the base surfaces of a heat sink.

Research has also been performed on the use of pin fin geometry in heat sinks immersed in liquids such as water. Such heat sinks, however, have small aspect ratios since water cools down the pin fins rapidly. For example, see J. J. Wei, “Effects of Fin Geometry on Boiling Heat Transfer from Silicon Chips with Micro-Pin-Fins Immersed in FC-72,” International Journal of Heat and Mass Transfer, 46 (2003) 4059-4070. Such heat sinks are not suitable for use for cooling in air which is a poor heat conductor.

### SUMMARY

One embodiment of the invention is directed to a device for transferring heat comprises a base member and a first array of pin fins supported by the base member, the pin fins having an aspect ratio of not less than about 10, and the pin fins being not more than about 0.3 mm in equivalent diameter and not more than about 3 mm in length, either one or both of the base member and pin fins comprising a metallic or semiconductor material.

Another embodiment of the invention is directed to a device for transferring heat comprises a heat spreader; and a plurality of heat transfer elements supported by and thermally connected to the heat spreader, each element comprising a base member, and an array of pin fins supported by the base member, the pin fins having an aspect ratio of not less than about 10 and the pin fins being not more than about 0.3 mm in equivalent diameter and not more than about 3 mm in length, the base members and/or pin fins comprising a metallic or semiconductor material.

Yet another embodiment of the invention is directed to a device for transferring heat comprises a set of fins arranged in a radial pattern; and a plurality of heat transfer elements supported on the fins, each element comprising a base member, and an array of pin fins supported by the base member, the pin fins having an aspect ratio of not less than about 10, and the pin fins being not more than about 0.3 mm in equivalent diameter and not more than about 3 mm in length, the base members and/or pin fins comprising a metallic or semiconductor material.

According to yet another embodiment of the invention, a device that dissipates heat in air is made as follows. A substrate is provided. A pattern is formed on the substrate, the pattern having holes therein or in the form of dots with cross-sectional dimensions of not more than about 0.3 mm. Pin fins supported by the substrate are formed, where the pin fins have an aspect ratio of not less than about 10, and not more than about 0.3 mm in equivalent diameter and not more than about 3 mm in length. Either one or both of the base member and pin fins comprise a metallic or semiconductor material. The pattern is then removed.

One more embodiment of the invention is directed to a method for transferring heat. The method comprises providing a device for transferring heat which comprises a base member and a first array of pin fins supported by the base member, the pin fins having an aspect ratio of not less than about 10, and the pin fins being not more than about 0.3 mm in equivalent diameter and not more than about 3 mm in length, the base member and/or pin fins comprising a metallic or semiconductor material. The method includes locating the base member relative to an object to transfer heat between the pin fins and the object and so that the pin fins are in contact with a gaseous environment to enable heat transfer between the pin fins and the gaseous environment.

### BRIEF DESCRIPTION OF THE DRAWINGS

FIG. 1A exemplifies a conventional pin-fin heat sink of the prior art, made of a thermally-conductive metal such as Aluminum Alloy 6063.

FIG. 1B is a rear view of the conventional pin-fin heat sink of FIG. 1A.

FIG. 1C illustrates a conventional radial-type prior art heat sink.

FIG. 2 illustrates another prior art heat transfer mechanism that transports heat via a heat pipe to the finned heat sinks, where the heat is dissipated to air.

FIGS. 3A, 3B, and 3C illustrate a representative geometrical model of a heat sink of one embodiment of the present invention, whose base surface is patterned with fine-scale pin fins.

FIGS. 3D, 3E, and 3F illustrate three kinds of pin fin cross-sections that are intended to increase the contact surface with air in embodiments of the present invention.

FIG. 3G illustrates one kind of pin fin cross-section to introduce the definition of equivalent diameter.

FIG. 3H shows a perspective view of an FSP heat sink of an embodiment of the present invention.

FIG. 3I presents a single pin fin from an FSP heat sink of an embodiment of the present invention, for the purpose of depicting its thermal conduction properties.

FIG. 4 illustrates a semiconductor fabrication process flow for making a micro-structure pin fin heat sink of an embodiment of the present invention.

FIG. 5 exemplifies a process for fabricating nano-scale carbon tubes as pin fins on a thermally conductive substrate.

FIG. 6 shows an FSP heat sink of an embodiment of the present invention, mounted to a heat spreader for transferring heat to air.

FIG. 7A shows multiple FSP heat sinks inserted or attached to a U-shaped heat spreader to multiply the heat dissipation capacity to air.

FIG. 7B shows composite metal layers deposited on the back side of an FSP heat sink for purposes of metal bonding.

FIG. 7C shows a highly thermally conductive material that is metallically bonded to an FSP heat sink.

FIG. 7D illustrates another embodiment of the present invention, in which an assembly of multiple FSP heat sinks is used to multiply the heat dissipation capacity of the system to air.

FIG. 8 shows a fan that has been added to the heat sink bank of FIG. 7A to further increase heat convection.

FIG. 9A illustrates the momentum and thermal boundary layers, respectively, of a natural convection flow along a smooth vertical wall.

FIG. 9B shows the natural convection flow between two FSP heat sinks.

FIG. 10 shows the forced convection flow between two FSP heat sinks.

FIGS. 11A and 11B show an embodiment of the present invention in which the base of the heat sink has perforated holes for increasing flow velocity perpendicular to the base, in order to enhance the heat transfer.

FIGS. 12A and 12B show an embodiment of the present invention in which heat gutters are created to facilitate carrying heat away from the pin fins.

### DETAILED DESCRIPTION OF THE PREFERRED EMBODIMENTS

At least some of the embodiments herein include a compact, low-profile heat sink with fine-structure patterned pin fins for increased heat transfer. These embodiments introduce fine-structure designs and their manufacturing methods to the field of heat sinks, to tremendously increase the contact surface with air, to increase heat flux density across the heat sink, to reduce the drag force on the flow of the fluid medium around the heat sink, and at the same time to keep the heat sink compact, with a low profile. The embodiments of the present invention have applications in the removal of heat from electronic components and devices, as well as any application where efficient heat transfer is desired. The fine-structure patterned (FSP) pin fins retain the typical aspect ratio of conventional pin fin heat sinks of the prior art, and also have a similar relationship between pin fin diameter and pin fin spacing. However, with much smaller pin fin diameter, the FSP pin fin heat sink of the present invention has many more pin fins, when compared to a conventional heat sink of similar base area, and the FSP pin fins are of greatly reduced height. This results in the FSP pin fin heat sink achieving heat transfer that is comparable to that of a conventional heat sink of similar base area, but with the FSP pin fins having a greatly reduced height dimension. Alternatively, an FSP pin fin heat sink can achieve much greater heat transfer, when compared to a conventional heat sink of similar volume. Multiple FSP pin fin heat sinks can be affixed to a common heat spreader, and it is also possible to fabricate FSP pin fin heat sinks with pin fins on both sides of a common base plate.

In some embodiments, a method is described for using semiconductor processing techniques to fabricate micro-structure PSP fin pin heat sinks, from a variety of thermally conductive substrate materials, including metals and semiconductor material. An alternative method is described for fabricating nano-scale carbon nano-tubes, or metallic nano-wires as pin fins on a thermally conductive substrate. /

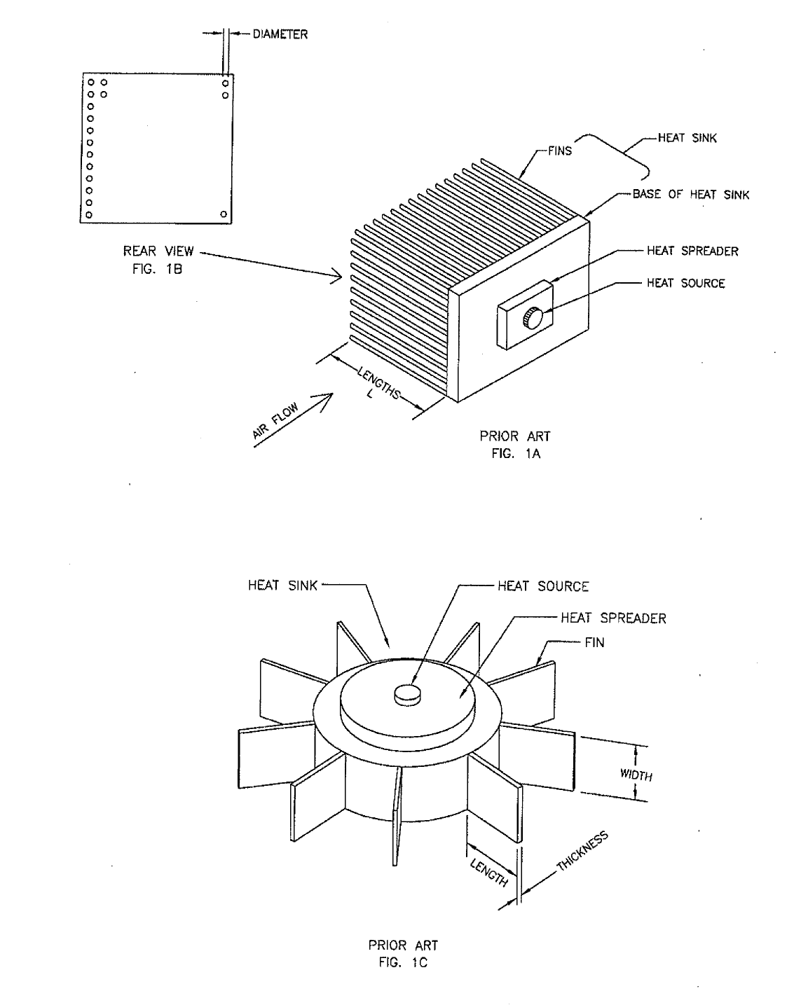

FIG. 1A shows a perspective view of a conventional prior art heat sink that has pin fins protruding out of a metal base. FIG. 1B is a rear view of the heat sink of FIG. 1A. The diameter or thickness of the pin fins is in the range of a few millimeters. The aspect ratio S of a pin is defined as the length L of a pin divided by its characteristic diameter Dₑ. The aspect ratio for the pin fins of a typical prior art heat sink with large diameters (of the order of a millimeter or more) obtained by means of forging or extrusion is on the order of ten. Therefore the typical length of the pin fins is in the range of tens of millimeters, resulting in conventional heat sinks being bulky. Especially for natural convection systems that need larger contact surface with air, heat sinks typically dominate the overall volume of a power generating electronic device. For example, about 75% of the electrical power consumed by Light Emitting Diode (LED) chips becomes a localized thermal heat source. It is critical for LEDs to reduce temperature, in order to ensure their performance and reliability. Heat sinks are usually used to dissipate heat from the heat source to air.

FIG. 1C shows another conventional prior art heat sink, using a radial arrangement of fins. The width and length of the pins are on the order of tens of millimeters.

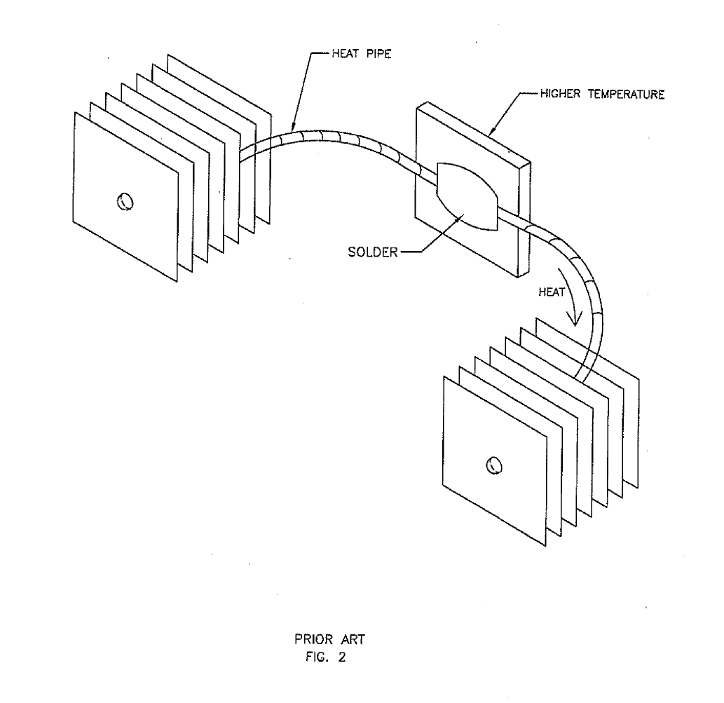

FIG. 2 illustrates another prior art heat transfer mechanism that transports heat via one or more heat pipes to the finned heat sinks where the heat is dissipated to air.

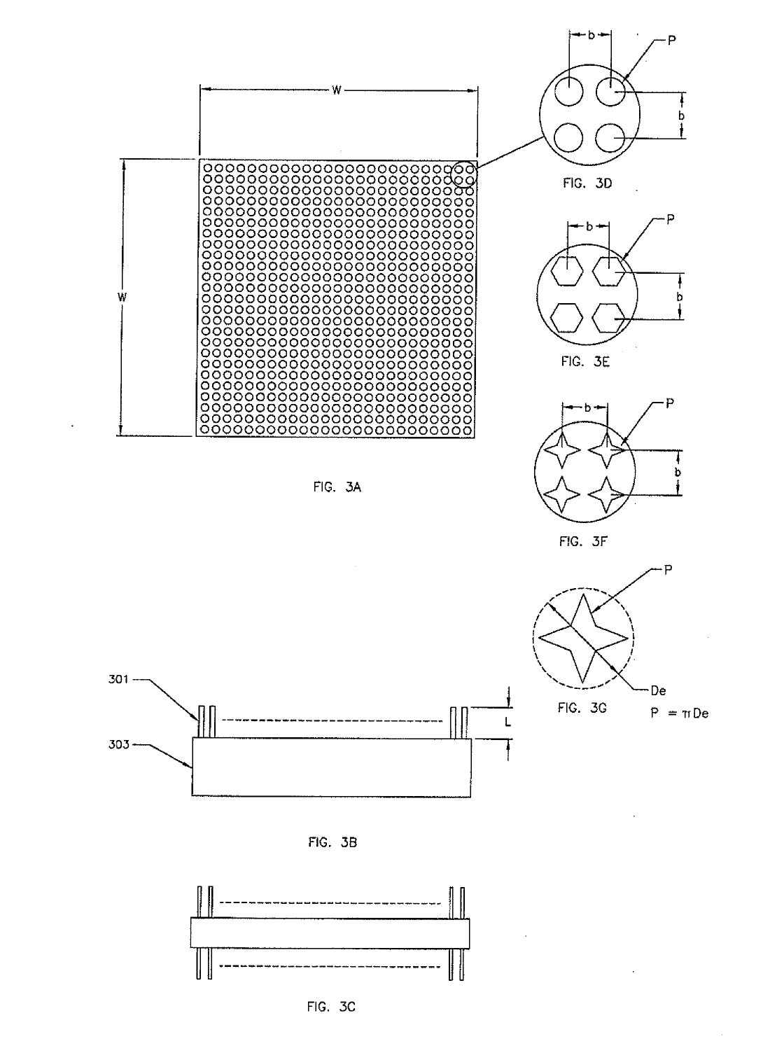

FIGS. 3A (front view) and 3B (side view) show an embodiment of the present invention, with a large number of pin fins (301) protruding out of a thermally conductive plate or base (303). Either one or both of the pin fins (301) plate (or base) (303) may comprise a metallic or semiconductor material. The length of each pin fin is L. FIG. 3C shows another embodiment of the present invention in which pin fins protrude from both the top and bottom surfaces of the thermally conductive base plate.

FIGS. 3D to 3F illustrate multiple embodiments of the pin fins of the present invention, with a variety of cross-sections. Non-circular cross-sections are implemented to increase the area of the contact surface with air. The pitch between pin fins is shown as dimension b. P denotes the length or dimension of the perimeter of a cross-section of the pin fin. For non-circular pin fin, the equivalent diameter Dₑ is defined as P divided by n. Thus, pin fins with differing cross-section shapes, but with the same perimeter dimension P, will have the same equivalent diameter Dₑ, and will also have the same equivalent diameter Dₑ as a pin fin with a circular cross section that has a circumference dimension equal to P. Note that for non-circular cross-section shapes, the effective diameter Dₑ will be larger than that of a minimal-size circle that just barely encloses the cross-section shape, as depicted in FIG. 3G.

The lattice configurations shown in FIGS. 3D to 3F are square for illustrative purpose. Other lattice configurations such as triangles and rectangles or other polygons are within the scope of the present invention.

Suppose the base plate (303) is a square with dimension W for each side.

$$\begin{matrix}Define M = \frac{total surface area contacting air}{surface area of base plate} \\ = \frac{{( \frac{W}{b} )}^{2} \cdot π {D}_{e} \cdot L + {W}^{2}}{{W}^{2}} \\ = 1 + \frac{π S}{{( \frac{b}{{D}_{e}} )}^{2}} where S = aspect ratio = \frac{L}{{D}_{e}} \\ \approx \frac{π S}{{( \frac{b}{{D}_{e}} )}^{2}} for fi \dot{n} s of large S ,\end{matrix} \qquad Equation ( 2 )$$

As an example, if

$$\frac{b}{{D}_{e}} = \frac{3}{2}$$

and S=15, then M=22.

Equation (2) shows that for two heat sink designs that are required to have the same air contact surface per unit base area, the required length of the pin fin (L) is inversely proportional to the equivalent diameter of the pin fin (Dₑ), if the lattice ratio b/Dₑ is fixed. For example, if the same contact surface with air is desired for both a conventional prior-art heat sink and the fine-structure patterned heat sink of the present invention, both of them having the same base size, the same pin fin aspect ratio of 15, and the same lattice ratio, then the length of the conventional pin fin of diameter 2 mm is 30 mm, but that of a pin fin having a diameter of 50 microns from a fine-structure pattern (FPS) heat sink is only 0.75 mm. Therefore the height of an FPS heat sink in the embodiment of FIGS. 3A-3H of the present invention is tremendously reduced without sacrificing the amount of contact surface with the surrounding air.

The fine-structure pin fins of the present invention can be created by either etching or chemical growth processes. Here two methods are introduced as examples, to illustrate processes for making fine-structure pin fins from a piece of thermally-conductive plate as a base.

### Semiconductor Processes for Making Fine-structure Patterned Pin Fins:

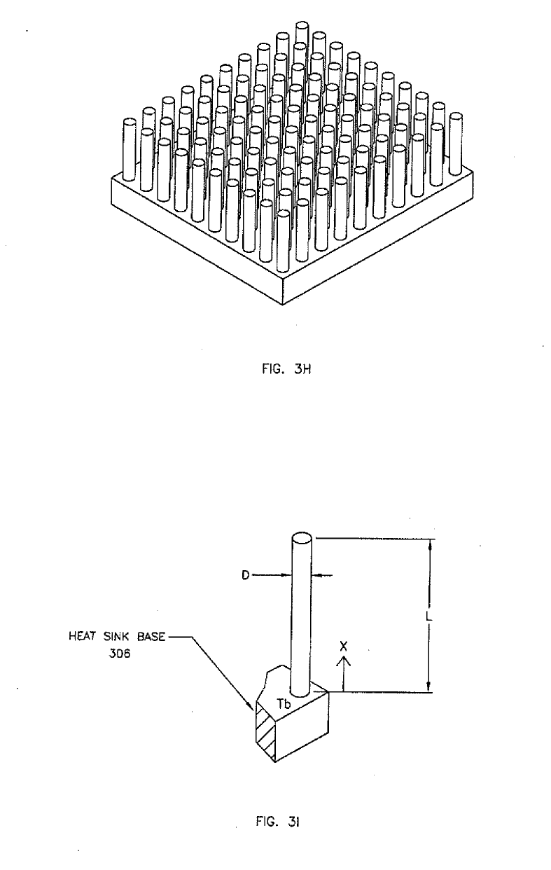

As illustrated in FIG. 4, a highly thermally-conductive material (401) such as silicon, having a thermal conductivity of about 149 w/m ° C., is selected as a substrate, as indicated in Step 1. The thickness of silicon or poly-silicon is of the order of a few millimeters. On top of the substrate is formed a silicon dioxide layer (408) of a thickness of a few micrometers grown by thermal oxidation or chemical vapor deposition. Photoresist (403) is spin-coated onto one surface of the silicon wafer as indicated in Step 2. Then photolithography is used to expose a fine-structure pattern into the photoresist, as indicated in Step 3. The optically exposed area of the photoresist (if positive photoresist is used) is washed out during the development. It is fairly easy to create photoresist dots (indicated by 405) with sizes ranging from a few microns to a few tens of microns, by using modern lithography technology. In Step 4, hydroflouride acid is used to chemically etch the silicon dioxide layer (408) that is not covered by the photoresist (405), which is then removed afterwards. Then a dry etching method, such as Deep Reactive Ion Etching (DRIE) is applied to dig deep recesses (as indicated by 406 in Step 5) in the area not covered by silicon dioxide (408). Current high-rate DRIE that directionally etches away silicon out of substrate 401 to create deep and steep holes, walls and trenches is able to etch pin fins having aspect ratios of 10 to 30. Bosch process that alternates repeatedly between isotropic ion etching and side-wall passivation is one of the most recognized DRIE technologies. Chemical wet etching is a cheaper alternative process that can also be implemented for aspect ratios less than 10. Finally, the remaining silicon dioxide is removed and a fine-structure patterned plate with an array of pin fins is then created, as shown in the perspective view of FIG. 3H. The above procedures can be applied again to the other side of the substrate (401) to create FSP pin fins on both sides of the base plate or substrate, as shown in FIG. 3C. The resulting double-sided FSP heat sink is even more compact and more heat efficient.

### Carbon Nano-tubes Grown on a Thermally Conductive Plate:

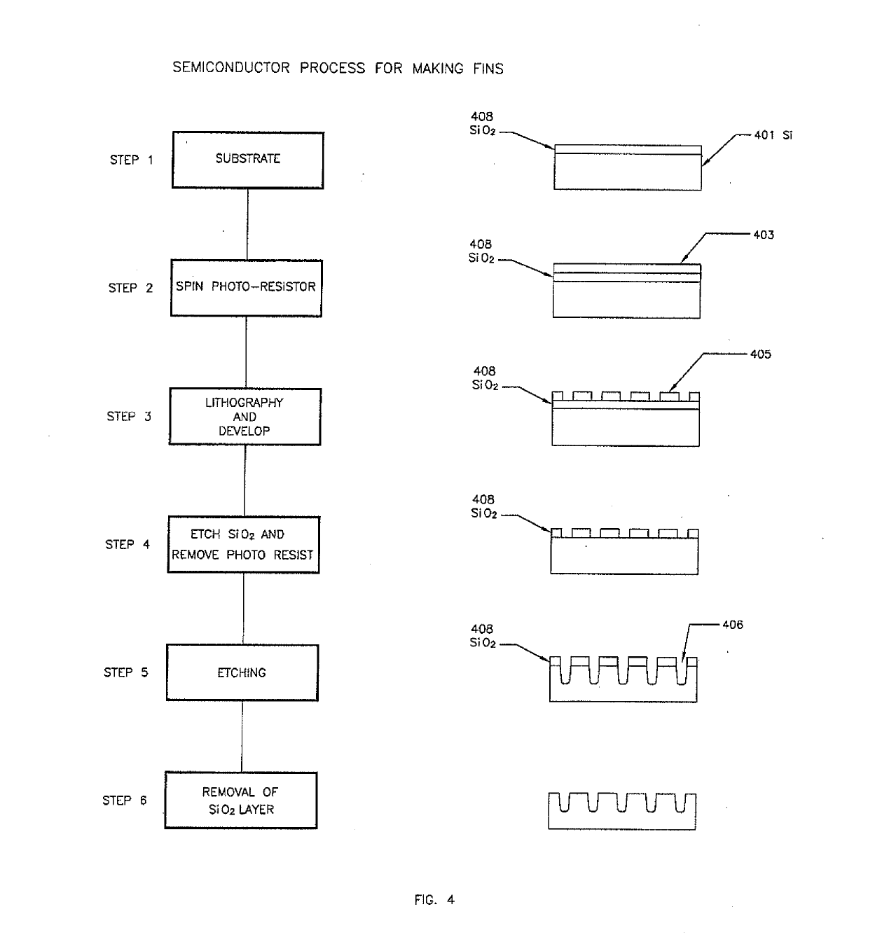

A thermally conductive plate or wafer (501), either made of metals such as copper (thermal conductivity K=398 w/m k) or aluminum 1100 (K=220 w/398/mk), or semiconductor materials such as silicon and SiC, is first selected, as indicated by Step 1 in FIG. 5. In Step 2 a thin polymer film (503) is coated onto the plate surface. In Step 3 a nano-scale pattern is introduced onto the polymer film (503) by either nano-scaled methods such as nano-imprinting from a template with a nano-scale pattern, or via UV photolithography. The patterned polymer film is shown as item 505 with voids (506) in the film. Then growing seeds (507) such as Fe₂O₃ for later growing of nano-tubes are deposited into the voids (506), as shown in Step 4. The unwanted polymer residual is removed in Step 5, leaving the growing seeds (507) exposed on the surface of the substrate (501). Then single-wall or multi-wall carbon nano-tubes are grown on the top of the growing seeds (507) by either chemical vapor deposition or wet chemical growth as shown in Step 6. It is well-known that carbon nano-tubes have thermal conductivity on the order of a few times to tens of times that of copper. The diameter of a carbon nano-tube ranges from a few nanometers to tens of nanometers. The above growing procedure can also be applied to the other side of the substrate (501). Also represented in FIG. 3C is a heat sink with nano-tubes grown on both sides, that is expected to provide super-efficient heat transfer.

Processes similar to the ones described above for growing carbon nano-tubes can also be applied to growing nano-wires, composed of metals such as transition metals, copper (Cu), silver (Ag, and gold (Au), as well as semiconductors such as silicon (Si), germanium (Ge), and indium arsenide (InAs), all having good thermal conductivity. Methods capable of growing the pin fins (301) in FIG. 3B, with diameters ranging from a few nanometers up to the sub-millimeter range, with a pin fin aspect ratio greater than about three or about ten, are all within the scope of the present invention. Preferably the nanotubes and nanowires have diameters of not more than 1 micron.

Molding methods may also be used for making pin fins having aspect ratio less than 3, but have a challenge for larger aspect ratio.

Laser ablation that sends high power laser pulses to ablate material over a surface line by line can also be a feasible method to create high aspect fine-structure fin pins out of a thermal conductive planar material though the production speed may be only moderate.

Other methods that are able to create fine-structure fins are also within the scope of the present inventions.

FIG. 3I shows a single pin fin taken from the heat sink in FIG. 3H. The temperature of the heat sink base (306) is T_{b}, whereas the temperature of the air or fluid around the heat sink is t_{∞}. The temperature distribution along the length of the pin fin, the heat flux from the heat sink base to the pin fin, and the pin fin heat transfer efficiency, respectively, are defined as follows ( See Gregory Nellis & Sanford Klein, Heat Transfer, Cambridge University Press, 2009.):

$$\begin{matrix}\frac{T - {T}_{∞}}{{T}_{b} - {T}_{∞}} = \frac{cosh ( m ( L - x ) ) + \frac{\overline{h}}{mk} sinh ( m ( L - x ) )}{cosh ( mL ) + \frac{\overline{h}}{mk} sinh ( mL )} & Equation ( 3 ) \\ {\dot{q}}_{fin} = ( {T}_{b} - {T}_{∞} \sqrt{\overline{h} per {kA}_{c}} \frac{\begin{matrix}sinh ( mL ) + \\ \frac{\overline{h}}{mk} cosh ( mL )\end{matrix}}{\begin{matrix}cosh ( mL ) + \\ \frac{\overline{h}}{mk} sinh ( mL )\end{matrix}} & Equation ( 4 ) \\ {η}_{fin} = \frac{[ tanh ( mL ) + {mLAR}_{tip} ]}{mL [ 1 + {mLAR}_{tip} tanh ( mL ) ] ( 1 + {AR}_{tip} )} & Equation ( 5 )\end{matrix}$$

where:
T_{b}=base temperature
T_{∞}=fluid (air) temperature
per=perimeter of the pin fin
L=length of the pin fin
T=temperature

$$mL = \sqrt{\frac{per \overline{h}}{{kA}_{c}}} L = pin fin constant$$

h̅=heat transfer coefficient
A_{c}=cross-sectional area of the pin fin
k=thermal conductivity
\dot{q}_{fin}=pin fin heat transfer rate
x=position (relative to base of pin fin)

$${AR}_{tip} = \frac{{A}_{c}}{per L} = tip area ratio$$

Generally the aspect ratio of a pin fin is large. The heat convection from the end tip of a pin fin is much smaller than that along the pin. Therefore, equations (3)-(5) can be simplified to:

$$\begin{matrix}\frac{T - {T}_{∞}}{{T}_{b} - {T}_{∞}} = \frac{cosh ( m ( L - x ) )}{cosh ( mL )} & Equation ( 6 ) \\ {\dot{q}}_{fin} = ( {T}_{b} - {T}_{∞} ) \sqrt{\overline{h} per {kA}_{c}} tan ( mL ) & Equation ( 7 ) \\ {η}_{fin} = \frac{tanh ( mL )}{( mL )} & Equation ( 8 )\end{matrix}$$

For free convection air flow whose heat transfer coefficient is less than 2 w/m²k and forced air flow whose heat transfer coefficient is generally less than 200 w/m²k, mL in equation (7) is much less than 1. Equation (7) and (8) are therefore approximated to

\dot{q} fin=π(T_{b}−T_{∞})S h̅ Dₑ² Equation (9)

η_{fin}→1 Equation (10)

Multiplying b⁻² to Equation (9), the heat flux across the heat sink's unit base area to the pin fins is π (T_{b}−T_{∞}) S h̅ (Dₑ/b)², which is dependent on the lattice ratio b/Dₑ. This concludes that the heat flux across the heat sink's unit base area for a FSP heat sink is same as that for a conventional bulk heat sink as long as the lattice ratio is kept same. Furthermore Equation 9 illustrates the heat dissipation to air per pin fin is proportional to aspect ratio S for free convection and forced air flows. Therefore it is desirable in the present invention to make aspect ratio as large as possible by methods such as modern DRIB, or by using nanotubes and nanowires as described above. In one embodiment, the aspect ratio S of the pin fins is not less than about 10. In another embodiment, the aspect ratio S of the pin fins is not less than about 20. The pin fins preferably have equivalent diameter of not more than about 0.3 mm, and length of not more than about 3 mm. In one embodiment, the length of the pin fins are less than about 1 mm. In still another embodiment, the pin fins preferably have equivalent diameter of not more than about 0.1 mm. The heat transfer coefficient of a liquid flow is generally one or two orders higher in magnitude than that of an air flow. Thus the temperature quickly drops along the pin fin so that a high aspect ratio (>5) has little additional benefit for heat dissipation to surrounding liquid.

Air blowing across the pin fins either by forced flow or by natural convection has a pressure drop due to the drag force induced by the fins. It is desirable that the pressure drop be as small as possible for a heat transfer device. The total drag force F_{D} induced by the pin fins is

$${F}_{D} = {C}_{D} \cdot {A}_{P} \cdot \frac{1}{2} ρ {U}_{∞}^{2}$$

where C_{D}=drag coefficient depending on geometry of pin fins, Reynold's number, as well as other factors
Aₚ=total projected area of the pin fins, facing the flow
ρ=air density
U_{∞}=air free stream velocity

The projected area of the pin fins per unit length of heat sink base is

$$\sim ( \frac{D}{b} ) \cdot L$$

Therefore, the drag force per unit length of heat sink base is proportional to L, assuming that the pin fin shapes are the same, and that the lattice ratio b/D is held constant for both bulk and FSP heat sinks, which is both achievable and practical. That reveals that the FSP heat sink has much less drag force than that of the conventional prior art heat sink.

In summary, based on the above illustrations and equations, the FSP heat sink of the present invention is not only one to two orders of magnitude smaller in pin fin length when compared to conventional prior art heat sinks, but is also superior in drag force reduction. An FSP heat sink as shown in FIG. 3H with pin fin length less than 1.0 mm should perform in heat transfer as good as a conventional prior art heat sink with pin fin length on the order of tens of millimeters, as shown in FIG. 1A.

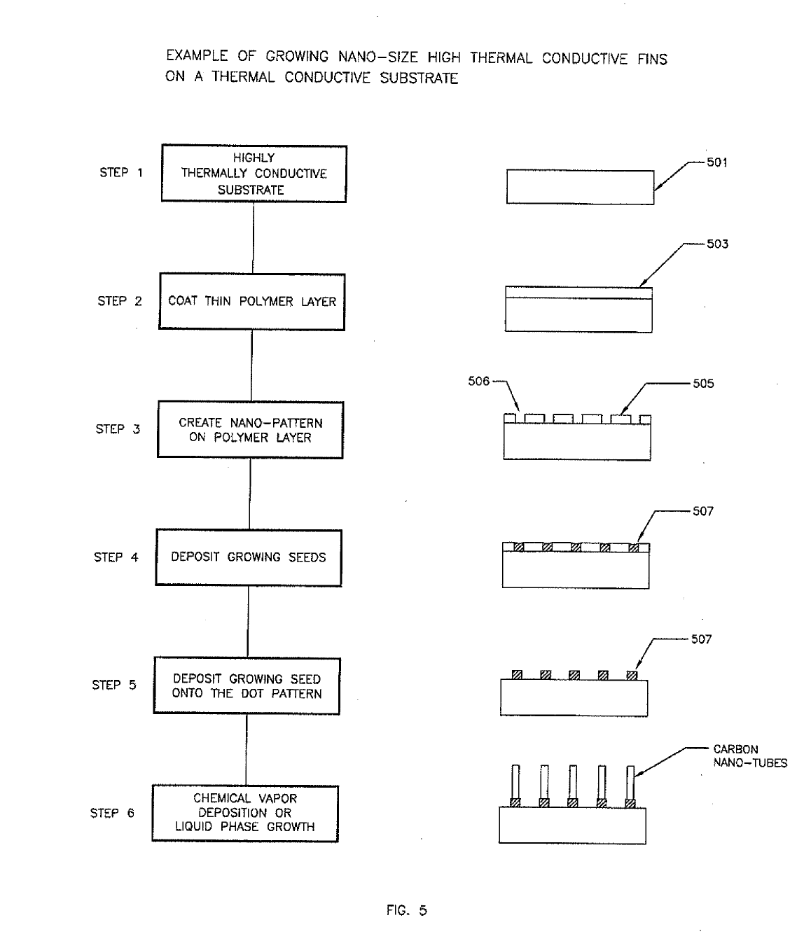

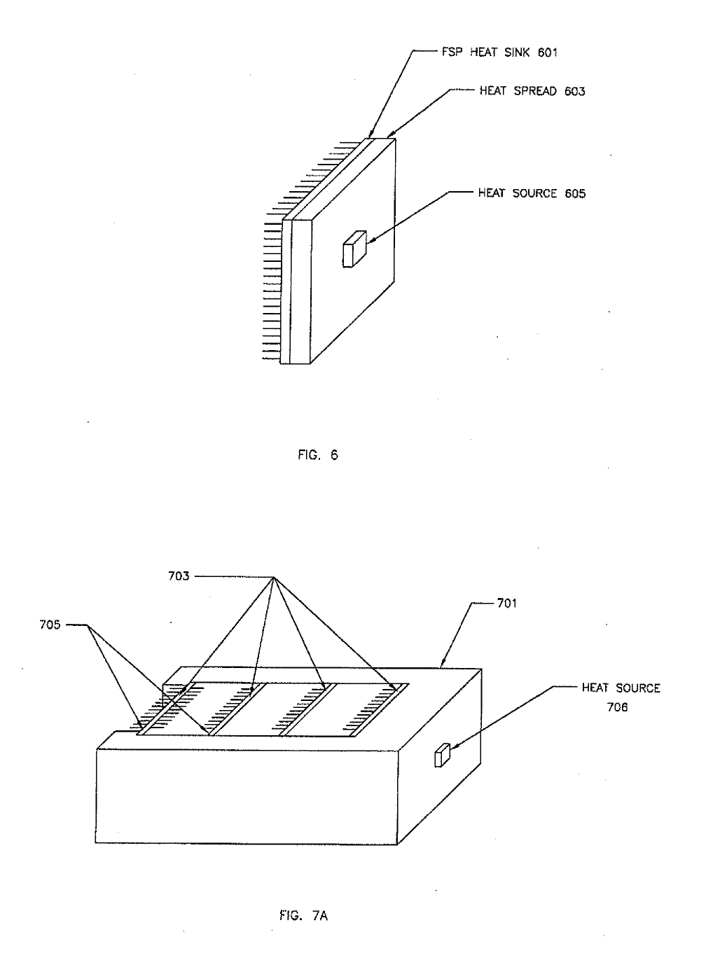

FIG. 6 shows an FSP heat sink (601) mounted directly onto the back side of a heat spreader (603) that has a heat source (605) on its front side. As compared to FIG. 1A, the FSP heat sink (601) is low-profiled and has a much smaller thickness. Because of their low profile, multiple FSP heat sinks (703), as shown in FIG. 7A, can be stacked up by tightly affixing them, or metallically bonding them to a highly thermally conductive metal U-shaped heat spreader (701), as long as the space between the FSP heat sinks is large enough to prevent degradation of their individual heat transfer coefficients.

The densely populated pin fins of an FSP heat sink are capable of dissipating a large amount of heat to air. In some situations the heat is transferred to the pin fins via the edges of the heat sink base such as is illustrated by item 705 in FIG. 7A and item 710 in FIGS. 7B and 7C. In some cases, as illustrated in FIGS. 7B and 7C, the base (720) of the FSP heat sink may be very thin, especially if a semiconductor wafer is being used as the base material, so that heat conduction is limited to the edge areas of the base (720). In this case, where such contact arrangement of the base (720) becomes the bottle neck for heat conduction, a highly thermally conductive material (715) such as copper can be metallically bonded (712) to the base (720) to increase the area for heat conduction to the pin fins (713). Thin composite metallic layers (719) such as Ti/Au/Sn may be deposited by either electrochemical plating or e-beam evaporation to the back side of the FSP heat sink as shown in FIG. 7B. Then the FSP heat sink assemblies of FIG. 7C can be used to replace the FSP heat sinks (703) in FIG. 7A.

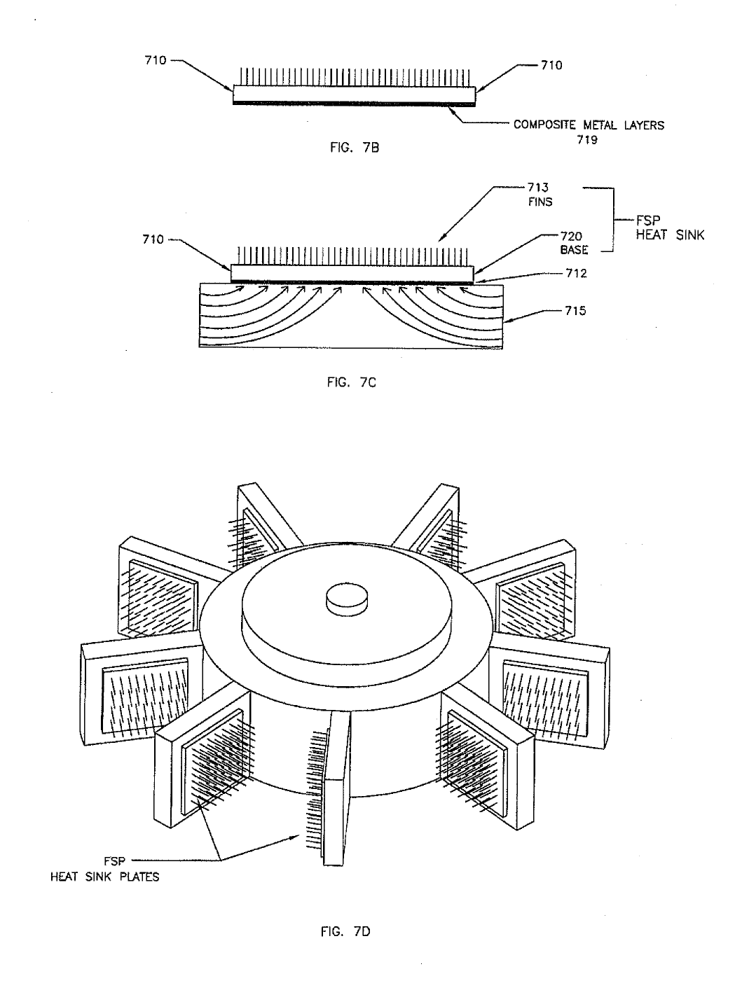

The FSP heat sink bank in FIG. 7A is able to draw a lot of heat from the heat source (706). A fan (801) in FIG. 8 can be mounted on one side of the heat sink bank in the embodiment of FIG. 7A as well as other embodiments herein to increase the flow of air past the heat sink bank, thereby providing further improvement in heat transfer.

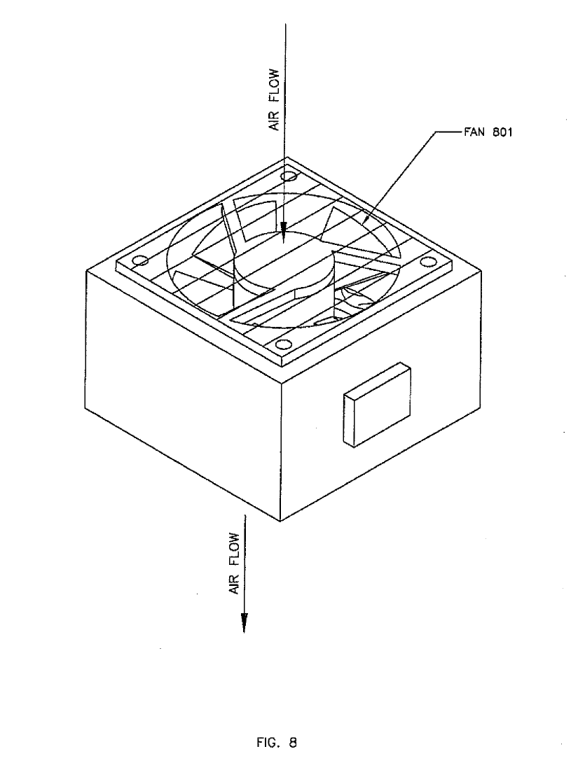

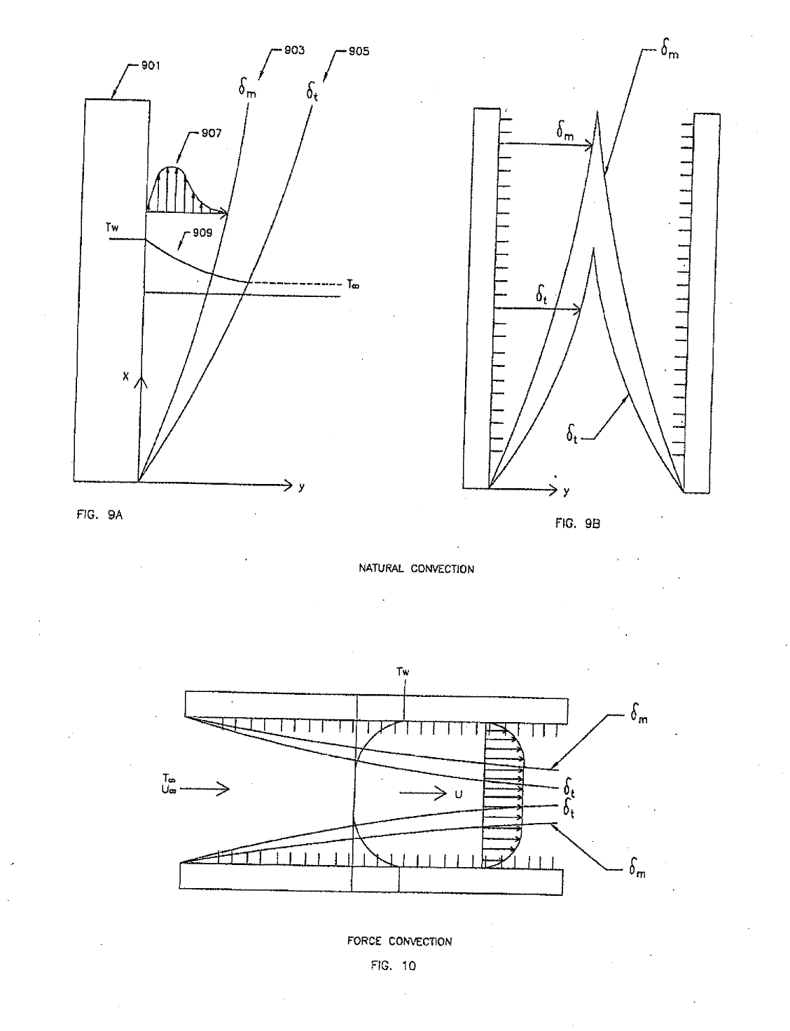

The flow field and the material properties of the surrounding fluid, as well as other minor parameters, determine the heat transfer coefficient hₜ in equation (1), and its corresponding dimensionless Nusselt number Nu. FIG. 9A pictorially represents the flow field and temperature profile of a laminar natural convection air flow along a heated vertical plate (901) with a temperature T_{w}. δₘ (903) and δₜ (905) indicate the momentum and thermal boundary layers, respectively. The velocity profile and the thermal distribution are indicated by items 907 and 909, respectively. As the surface of plate is densely populated with fine-structure patterned fins, the momentum and thermal boundary layer are expected to grow thicker, more quickly than that of a smooth plate, due to more vigorous transport vertical to the plates. FIG. 9 B sketches the flow field profiles. FIG. 10 pictorially illustrates how forced convection flow fields are developed between two FSP plates. By scaling laws and empirical data, the heat transfer coefficient of an FSP plate is expected to be of the same order of magnitude as that of smooth plate. However, the FSP plate has a contact surface area with air that is at least two orders of magnitude greater than that of a smooth plate, leading to a proportional increase in overall heat transfer.

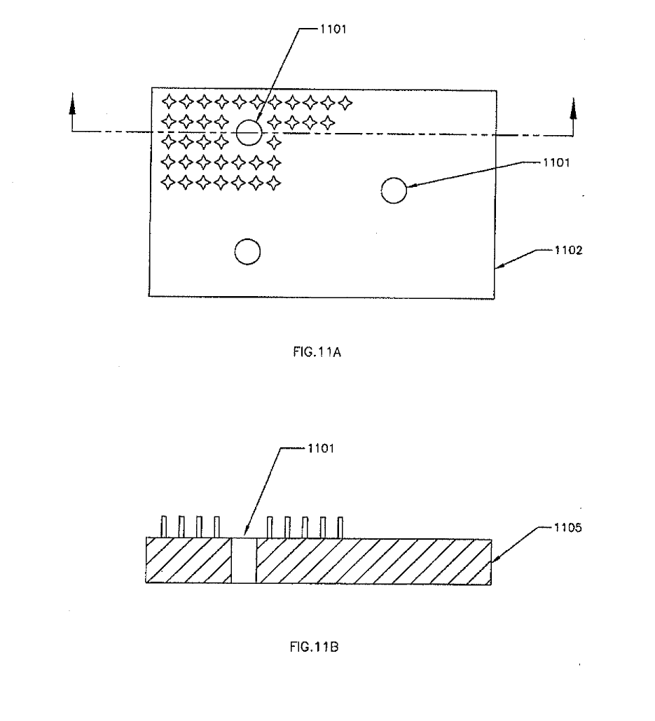

Perforated holes, as indicated by item 1101 in FIG. 11A, may be drilled through the base plate (1105) of the FSP heat sink (1102), to generate a flow perpendicular to the base plate's surface, thereby causing thermal boundary layer bursting or circulation, leading to increased flow turbulence for enhanced heat convection.

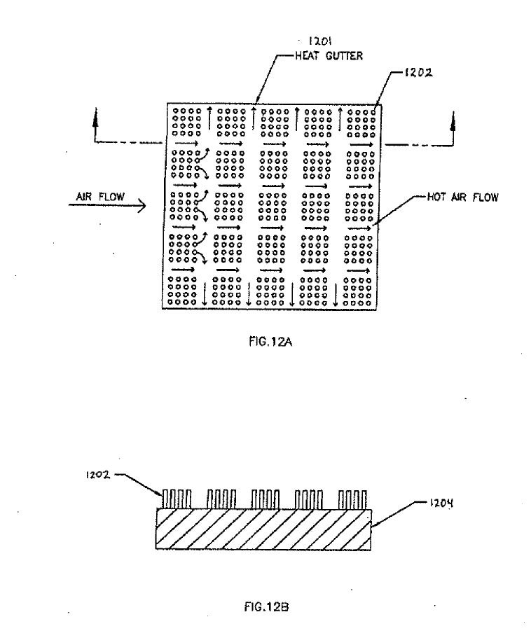

In addition to the perforated holes (1101) in FIG. 11A, the heat gutters (1201) shown in FIGS. 12A and 12B are created between sub-arrays or groupings of densely populated pin fins 1202) to facilitate carrying heat away from pins. Resulting from patterning during the fabrication process, heat gutter shape and geometry can be arranged arbitrarily among the sub-arrays or groupings of densely populated pin fins (1202) over the heat sink's base plate (1204), for optimal heat transfer.

The above FSP heat sink can be used conversely to suck heat from the surrounding media to provide heat to an object. Due to large contact surface provided by FSP fins, the transient time for the heated body to reach thermal equilibrium is reduced. For example, FSP heat sink in the present invention can be attached to a biological culture tube or a chemical beaker that endo-thermal reaction is taking place to timely keep the testing sample in constant temperature by quickly absorbing heat from the surrounding heat reservoir.

Resulting from that fact of that the surface area of the FSP heat sink is one to two orders larger in magnitude larger than that of a plane surface. As FSP heat sink is attached to an elevated hot body, a FSP heat sink can radiate a significant amount of heat by thermal radiation as it is attached to an elevated hot body. Conversely, the FSP can be used to absorb radiation energy from the environment to heat up a cooler body. Thus, the heat transfer can take place by radiation, as in black body radiation, as well as by conduction and/or convection. All in all the FSP heat sink is benefited by its low profile.

Pin fins have been used in the present invention to illustrate the advantages of the fine-structure patterned heat sink. Other fin shapes such as straight plate fins and curved plate fins with either or both of their width and thickness less than one millimeter and high aspect ratio (defined by height divided by either of width and thickness, whichever is the smaller) and are directed built by patterning from a thermal conductive substrate are also within the scope of the present invention.

While the invention has been described above by reference to various embodiments, it will be understood that changes and modifications may be made without departing from the scope of the invention, which is to be defined only by the appended claims and their equivalents.

1. A device for transferring heat comprising:
a base member; and
at least a first array of pin fins and a second array of pin fins supported by said base member, said first and second arrays separated from one another, said pin fins having an aspect ratio of not less than about 10, and said pin fins being not more than about 0.3 mm in equivalent diameter and not more than about 3 mm in length, either one or both of said base member and Pin fins comprising a metallic or semiconductor material.

2. The device of claim 1, the base member comprising a layer of silicon or metallic material, said device further comprising a second member bonded to the base member for conducting heat between the pin fins and the second member through the base member.

3. The device of claim 1, wherein said base member defines one or more holes therein for enhancing air flow turbulence and heat convection to transfer heat.

4. The device of claim 1, said device further comprising additional arrays of pin fins, said additional arrays and said first and second arrays of pin fins arranged with gutters between the arrays for enhancing heat convection to transfer heat.

5. The device of claim 1, further comprising a fan for generating air flow in spacings between the pin fins.

6. The device of claim 1, said first array of pin fins and second array of pin fins being supported by said base member on opposite sides of said base member.

7. The device of claim 1, said pin fins having an aspect ratio of not less than about 20.

8. The device of claim 1, said pin fins having a perimeter P, wherein said equivalent diameter of the pin fins is P/π.

9. The device of claim 1, said pin fins having a length or lengths less than about 1 mm.

10. The device of claim 1, said pin fins having an equivalent diameter less than about 0.1 mm.

11. A method for making a device that dissipates heat in air, comprising:
providing a substrate;
forming a first pattern on a first side of the substrate, said first pattern having holes therein or in the form of dots with cross-sectional dimensions of not more than about 0.3 mm; and
causing pin fins supported by the substrate to be formed by an etching process so that said pin fins have an aspect ratio of not less than about 10, and said pin fins being not more than about 0.3 mm in equivalent diameter and not more than about 3 mm in length, said base member and pin fins comprising a metallic or semiconductor material; and
removing said first pattern.

12. The method of claim 11, wherein said first pattern is in the form of dots and formed by means of a photolithographic process.

13. The method of claim 11, wherein said pin fins are formed by means of a Deep Reactive Ion etching process.

14. The method of claim 11, wherein said pin fins are formed by a dry etching process.

15. The method of claim 11, wherein said pin fins are formed by a Bosch process that alternates repeatedly between isotropic ion etching and side-wall passivation.

16. The method of claim 11, further comprising:
forming a second pattern on a second side of the substrate opposite to that of the first side, said second pattern having holes therein or in the form of dots with cross-sectional dimensions of not more than about 0.3 mm; and
causing pin fins supported by the substrate to be formed on the second side of the substrate by an etching process so that said pin fins have an aspect ratio of not less than about 10, and said pin fins being not more than about 0.3 mm in equivalent diameter and not more than about 3 mm in length, said base member and pin fins comprising a metallic or semiconductor material; and
removing said second pattern, thereby forming a double sided fine-structure patterned heat sink.

17. A method for transferring heat, comprising:
providing a device for transferring heat which comprises:
a base member; and
a first array of pin fins and a second array of pin fins supported by said base member, said pin fins having an aspect ratio of not less than about 10, and said pin fins being not more than about 0.3 mm in equivalent diameter and about 3 mm in length, said base member and pin fins comprising a metallic or semiconductor material;
locating said base member relative to an object to transfer heat between the pin fins and the object and so that said pin fins are in contact with a gaseous environment to enable heat transfer between the pin fins and the gaseous environment; and
generating air flow in spacings between the pin fins and between the first and second arrays of pin fins.

18. The method of claim 17, wherein heat is transferred from the object to the pin fins, and said pin fins are in contact with air.

19. The method of claim 17, wherein heat transfer is by means of conduction or radiation or both.
